(19) United States
(12) Patent Application Publication
(10) Pub. No.: US 2025/0201575 A1
(43) Pub. Date: Jun. 19, 2025

(54) SELECTIVE DEPOSITION FOR MITIGATING CORNER LOSS IN SEMICONDUCTOR FABRICATION

(71) Applicants: Nederlandse Organisatie voor Toegepast-natuurwetenschappelijk onderzoek TNO, Gravenhage (NL); Tokyo Electron Limited, Tokyo (JP)

(72) Inventors: Alfredo Mameli, Eindhoven (NL); Kandabara Tapily, Albany, NY (US)

(21) Appl. No.: 18/984,294

(22) Filed: Dec. 17, 2024

Related U.S. Application Data
(60) Provisional application No. 63/611,543, filed on Dec. 18, 2023.

(51) Int. Cl. H01L 21/311; H01L 21/768

(52) U.S. Cl. CPC H01L 21/31116; H01L 21/31144; H01L 21/768

(57) ABSTRACT

Some aspects of the inventive concepts relate to methods for mitigating corner loss in semiconductor fabrication. The methods can include performing a first etching process to selectively expose corner portions of a first material layer within a multi-layered semiconductor structure by removing portions of a second material layer adjacent to the first material layer. The exposed corner portions can undergo a surface treatment comprising a pretreatment process to modify chemical or physical properties and functionalization with a surface-modifying agent to enable selective deposition. A protective material can be selectively deposited onto the corner portions of the first material layer. In some aspects, a second etching process can be performed to remove additional portions of the multi-layered structure, with the protective material mitigating etch-induced degradation or structural impacts on the corner portions, thereby enhancing precision and reliability in semiconductor device fabrication.

### RELATED APPLICATIONS

This application claims priority to U.S. Provisional Patent Application No. 63/611,543, filed on Dec. 18, 2024, entitled “Selective Deposition for Preventing Corner Loss,” which is hereby incorporated by reference in its entirety.

### FIELD

The present inventive concept relates to semiconductor manufacturing processes, more specifically to techniques used in the etching of self-aligned contacts (SAC) in the fabrication of semiconductor devices.

### BACKGROUND

The ongoing miniaturization of semiconductor devices presents significant challenges in maintaining structural integrity during fabrication. Processes involving aggressive etching steps, such as those for defining fine features, often lead to corner loss, pinch-off, and related defects, particularly in silicon nitride (SiN) layers used as spacers or protective caps. Such defects can compromise device functionality and reduce fabrication yields.

Approaches to address these issues include atomic layer etching (ALE), increasing the thickness of SiN layers, or modifying gate stack configurations. However, these methods often introduce trade-offs such as reduced throughput, increased process complexity, or undesirable changes to feature topography and aspect ratios.

### SUMMARY

Some aspects of the inventive concepts relate to methods for mitigating corner loss in semiconductor fabrication. The methods can include performing a first etching process to selectively expose corner portions of a first material layer within a multi-layered semiconductor structure by removing portions of a second material layer adjacent to the first material layer. The exposed corner portions can undergo a surface treatment comprising a pretreatment process to modify chemical or physical properties and functionalization with a surface-modifying agent to enable selective deposition. A protective material can be selectively deposited onto the functionalized corner portions of the first material layer, facilitated by chemical selectivity, surface reactivity, or steric hindrance associated with the surface-modifying agent. In some aspects, a second etching process can be performed to remove additional portions of the multi-layered structure, with the protective material mitigating etch-induced degradation or structural impacts on the corner portions, thereby enhancing precision and reliability in semiconductor device fabrication.

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1 illustrates a carousel-type reactor, which can be employed for ASD processes.

FIGS. 2A-2G illustrate a schematic representation of area-selective atomic layer deposition (AS-ALD) processes for thermal TiO₂ and plasma TiON on silicon nitride (SiN) as a growth surface (GS) and silicon dioxide (SiO₂) as a nongrowth surface (NGS).

FIG. 3 illustrates a self-aligned block (SAB) patterning process incorporating ASD hardmask deposition.

FIGS. 4A-4C present results demonstrating how CF₄/N₂ plasma pretreatment and subsequent back-etching cycles influence selective deposition.

FIG. 5 provides a graphical representation of deposition thickness as a function of the number of spatial ALD cycles for thermal TiO₂ at 100° C. and 200° C., as well as plasma TiON at 200° C.

FIG. 6 presents high-resolution SEM and TEM images showcasing the selectivity and uniformity of plasma TiON deposition on patterned substrates.

FIG. 7A depicts an example structure that can be utilized in semiconductor device fabrication.

FIG. 7B depicts an etching process applied to selectively expose portions of a first layer of the structure of FIG. 7A.

FIG. 7C illustrates an example of the selective deposition of a hard-mask material onto at least some of the exposed surfaces of the first layer.

FIG. 7D illustrates a subsequent etching step applied to the structure.

FIG. 7E illustrates an example structure with the selectively deposited hard-mask and initial hard mask removed, and metal filling performed to create the S/D contacts.

### DETAILED DESCRIPTION

Semiconductor device fabrication is a critical process in modern technology, requiring precise control over material deposition, etching, and patterning to produce reliable and scalable devices. Conventional self-aligned contact (SAC) etch techniques often encounter challenges such as corner loss of silicon nitride (SiNₓ) spacers, pinch-off, and tapering, which can compromise device performance and manufacturability. These challenges highlight the need for improved methods to enhance etch selectivity, minimize material damage, and maintain process consistency during SAC fabrication.

The inventive concepts described herein improve semiconductor device fabrication by employing processes such as selective material deposition, tailored etching chemistries, and sacrificial hard-mask layers to address challenges in SAC fabrication. For example, a hard-mask material can be selectively deposited onto exposed SiNₓ spacers using chemical vapor deposition (CVD) or atomic layer deposition (ALD). This hard-mask material can form a protective barrier, mitigating damage to the SiNₓ spacers during subsequent etching steps while facilitating the precise removal of surrounding materials, such as silicon dioxide (SiO₂). In some cases, the inventive concepts include a surface treatment preceding this deposition. The surface treatment can include a plasma process, such as a CFₓ-based plasma, for removing native oxide layers and partially fluorinating both the SiO₂ (nongrowth surface, NGS) and SiN (growth surface, GS). Following the plasma process, silane-based inhibitors, such as dimethylamino-trimethylsilane (DMATMS), hexamethyldisilazane (HMDS), or tris(dimethylamino)silane (TDMAS), can be applied to preferentially functionalize the SiO₂ surface (NGS). This functionalization inhibits deposition on the SiO₂ surface while allowing deposition on the SiN surface. Although silane inhibitors can adsorb to a minor extent on SiN, their preferential interaction with SiO₂ enhances selectivity for deposition on SiN.

Some inventive concepts described herein provide mechanisms for achieving enhanced selectivity and process control by utilizing tailored etching chemistries. These chemistries can include fluorinated compounds, such as CF₄ or CHₓF_{γ}-based mixtures, which react preferentially with certain materials, creating chemical contrasts that enable precise material removal. For example, the first etching process can employ fluorinated etchants, including CH₄F₂, carbon tetrafluoride (CF₄), or octafluorocyclobutane (C₄F₈), to selectively expose corner portions of silicon nitride (SiNₓ) layers. By incorporating inhibitors, such as silane-based compounds, deposition processes can selectively passivate surfaces, ensuring accurate placement of hard-mask materials and reducing unintended deposition on adjacent layers. This approach allows for efficient material patterning while maintaining compatibility with advanced device architectures.

Some inventive concepts described herein relate to the integration of selective hard-mask deposition with etching techniques to protect critical structural layers during SAC fabrication. This deposition can utilize precursors, such as titanium tetrachloride (TiCl₄) combined with ammonia (NH₃), nitrogen (N₂) and hydrogen (H₂), or water vapor (H₂O), or alternative precursors like tetrakis(dimethylamino)titanium (TDMAT) or bis(ethylmethylamino)titanium (BEMAT), to deposit materials such as titanium oxynitride (TiON), titanium nitride (TiN), titanium dioxide (TiO₂), hafnium oxynitride (HfON), or hafnium dioxide (HfO₂). The deposited materials can adhere selectively to SiNₓ (growth surfaces, GS) due to enhanced surface reactivity or steric hindrance introduced by the inhibitors, while deposition is blocked on nongrowth surfaces (NGS), such as SiO₂ or low-k dielectrics, including carbon-doped SiO₂ or fluorine-doped SiO₂. These hard-mask materials can be deposited with a step coverage of at least 90%, ensuring conformal protection of critical regions.

Some inventive concepts described herein relate to the removal of sacrificial hard-mask layers and the formation of source/drain (S/D) contact regions in semiconductor devices. For example, after selective deposition and etching steps, hard-mask layers can be removed using wet etching with hydrofluoric acid (HF) solutions or dry plasma-based techniques. Exposed regions, such as S/D contact areas, can then be filled with metals like tungsten (W), copper (Cu), or cobalt (Co), ensuring structural integrity and electrical performance. This method allows for the seamless integration of S/D contacts into advanced semiconductor architectures while reducing material damage and process variability.

Some inventive concepts described herein represent significant advancements in semiconductor device fabrication, particularly in improving the accuracy and efficiency of SAC processes. By combining selective hard-mask deposition, tailored etching chemistries, and precise removal techniques, these inventive concepts enable reliable and scalable manufacturing of semiconductor devices. The disclosed techniques address challenges associated with material selectivity, structural integrity, and process consistency, offering practical solutions to meet the demands of modern semiconductor technologies.

### Area-Selective Deposition (ASD) in Semiconductor Manufacturing

ASD processes can facilitate material growth on specific surfaces, such as silicon nitride (SiN), while limiting or avoiding deposition on nongrowth surfaces, such as silicon dioxide (SiO₂). Despite the advantages, achieving high selectivity between SiN and SiO₂ can present challenges due to their similar surface chemistries. Strategies involving surface functionalization, such as inhibitor dosing with small molecules, and pretreatment steps like plasma etching have demonstrated their potential to enhance selectivity by creating chemical contrasts. Integrating pre-cleaning, functionalization, deposition, and correction steps within a single system can also streamline workflows, reduce contamination risks, and improve process efficiency.

The use of carousel-type reactors in ASD processes can offer a platform for addressing these challenges. Such reactors are designed to support high-throughput ASD processes by combining plasma etching, inhibitor dosing, and precursor/co-reactant exposure zones within a single system. This integrated approach can facilitate continuous surface treatment and deposition workflows, limiting reoxidation of exposed SiNₓ spacer corners and improving process consistency. The substrate holder can rotate at adjustable speeds to allow controlled exposure times for each processing step. Plasma etching zones can deliver CF₄/N₂ chemistry to remove native oxides from SiN growth surfaces (GSs), which can enhance surface reactivity. Inhibitor dosing zones can deposit silane-based inhibitors, such as (N,N-dimethylamino)trimethylsilane (DMATMS), which can selectively passivate hydroxyl groups on SiO₂ nongrowth surfaces.

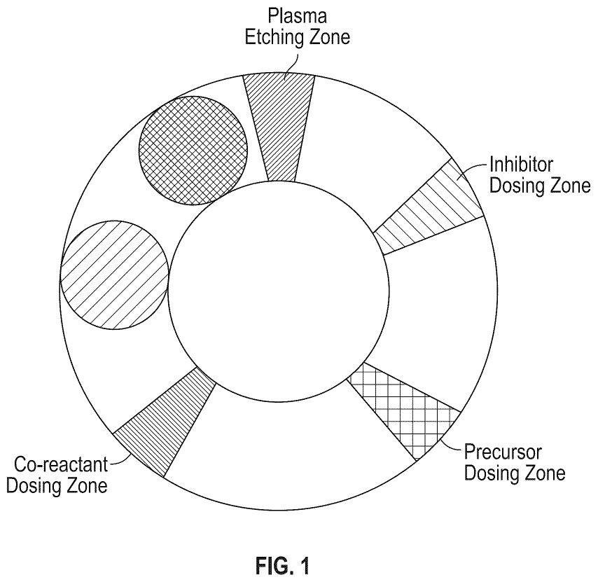

FIG. 1 illustrates a carousel-type reactor, which can be employed for ASD processes. The reactor can include a rotating substrate holder that can accommodate multiple substrates and an injector head equipped with dedicated zones for plasma etching, inhibitor dosing, and precursor/co-reactant exposure. The substrate holder can rotate at adjustable speeds to allow controlled exposure times for each processing step. Plasma etching zones can deliver CF₄/N₂ chemistry to remove native oxides from SiN growth surfaces (GSs), which can enhance surface reactivity. Inhibitor dosing zones can deposit silane-based inhibitors, such as (N,N-dimethylamino)trimethylsilane (DMATMS), which can selectively passivate hydroxyl groups on SiO₂ nongrowth surfaces (NGSs). Precursor and co-reactant zones can be configured to facilitate alternating exposures to chemicals, such as titanium tetrachloride (TiCl₄) and H₂O or N₂/H₂ plasma, to enable ASD of TiO₂ or TiON.

Such a design can integrate multiple stages, such as pre-cleaning, functionalization, deposition, and optional back-etching steps, into a continuous workflow. The carousel reactor's configuration can support high selectivity and controlled material growth, helping to manage process variability and reduce contamination risks. Such a system can be particularly suitable for semiconductor manufacturing processes requiring complex patterning schemes, offering the flexibility and efficiency needed to address evolving industry requirements.

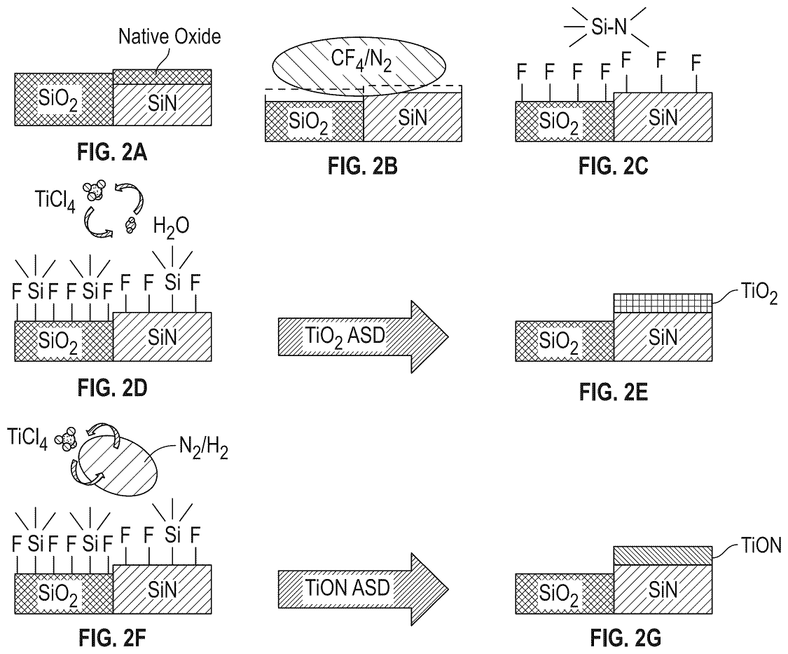

FIGS. 2A-2G illustrate a schematic representation of area-selective atomic layer deposition (AS-ALD) processes for thermal TiO₂ and plasma TiON on silicon nitride (SiN) as a growth surface (GS) and silicon dioxide (SiO₂) as a nongrowth surface (NGS).

FIG. 2A shows the initial substrate with SiN covered by a native oxide layer and adjacent SiO₂ regions.

FIG. 2B depicts the removal of the native oxide layer from the SiN surface using CF₄/N₂ plasma etching, exposing a partially fluorinated SiN surface and a modified SiO₂ surface.

FIG. 2C represents the surface chemistry following plasma treatment, with fluorine passivation observed on both SiN and SiO₂ surfaces.

FIG. 2D illustrates the application of alternating pulses of TiCl₄ and H₂O for thermal TiO₂ deposition. This approach can result in selective deposition of TiO₂ on SiN while minimizing deposition on SiO₂.

FIG. 2E shows the outcome, with a TiO₂ layer selectively deposited on SiN, with negligible or no deposition on SiO₂.

FIG. 2F depicts alternating exposures of TiCl₄ and N₂/H₂ plasma to achieve selective deposition of TiON on the SiN surface. FIG. 2G shows the final state, with TiON selectively deposited on SiN and limited deposition on SiO₂. This sequence outlines the use of plasma pretreatment and controlled deposition cycles to achieve desired selectivity.

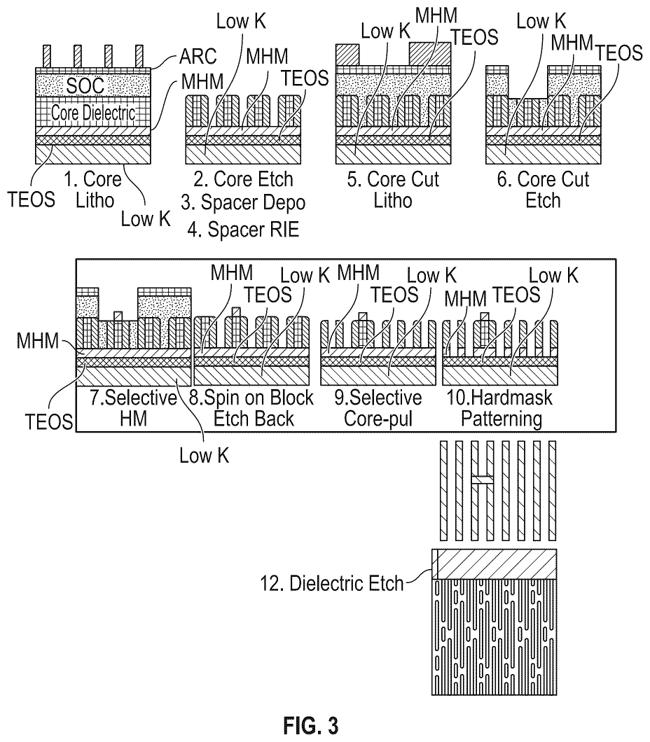

FIG. 3 illustrates a self-aligned block (SAB) patterning process incorporating ASD hardmask deposition. The process can simplify conventional SAB workflows by reducing the number of processing steps. After initial lithography and spacer patterning steps (core lithography, spacer deposition, and spacer RIE), ASD is employed to selectively deposit hardmask materials such as TiO₂ or TiON onto SiN surfaces. This eliminates the need for multiple spin-on block coating and etching steps, as seen in traditional SAB processes, while enabling higher pattern densities and improved edge placement accuracy. Following selective deposition, additional etching and cleaning steps may be performed to refine the pattern transfer, enhancing efficiency and reducing material usage in advanced patterning applications.

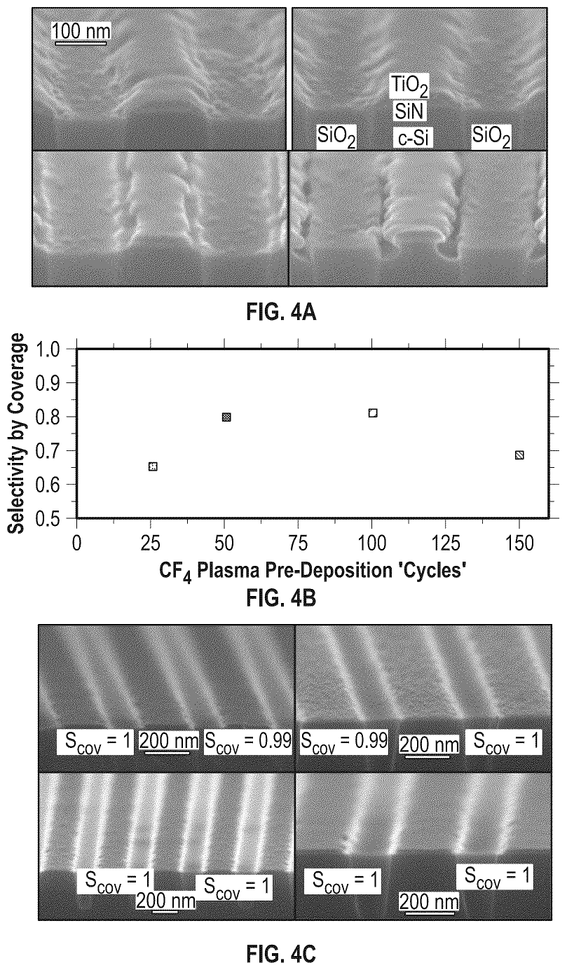

FIGS. 4A-4C present results demonstrating how CF₄/N₂ plasma pretreatment and subsequent back-etching cycles influence selective deposition.

FIG. 4A provides tilted-view SEM images displaying the results of different CF₄/N₂ plasma etching cycles (e.g., 25, 50, 100, and 150 cycles) applied to patterned SiN and SiO₂ surfaces. These images show how TiO₂ deposition on SiN is influenced by the number of pretreatment cycles.

FIG. 4B presents a graph of the selectivity (coverage ratio of GS to NGS) as a function of CF₄/N₂ plasma pretreatment cycles. The data indicate that an intermediate number of etching cycles can provide balanced fluorination of the surfaces, reducing unintended deposition or defects.

FIG. 4C displays SEM images highlighting selectivity and coverage under different conditions, including changes in deposition temperature (100° C. versus 200° C.) and the inclusion of back-etching steps. High selectivity (S˜0.99-1.00) can be achieved with optimized plasma pretreatment and back-etching adjustments.

These results illustrate how plasma exposure and deposition parameters can be adjusted to refine selectivity and reduce unwanted material deposition.

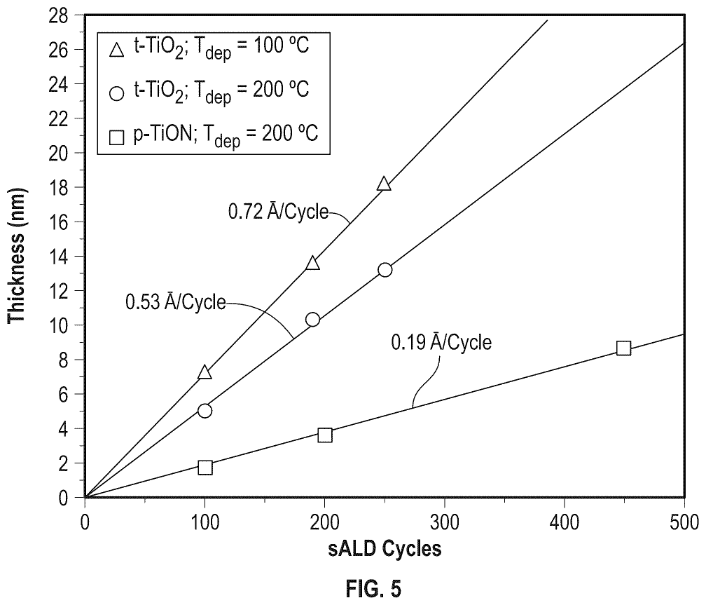

FIG. 5 provides a graphical representation of deposition thickness as a function of the number of spatial ALD cycles for thermal TiO₂ at 100° C. and 200° C., as well as plasma TiON at 200° C. The growth per cycle (GPC) values for each process are shown, with consistent thickness increments observed for TiO₂ and TiON on SiN growth surfaces. Minimal deposition is recorded on SiO₂ nongrowth surfaces, indicating high selectivity. These results demonstrate the tunability of layer thickness and the scalability of the process for achieving targeted material properties in advanced applications. The data also highlight the effect of processing temperatures and precursor/co-reactant combinations on GPC and overall selectivity.

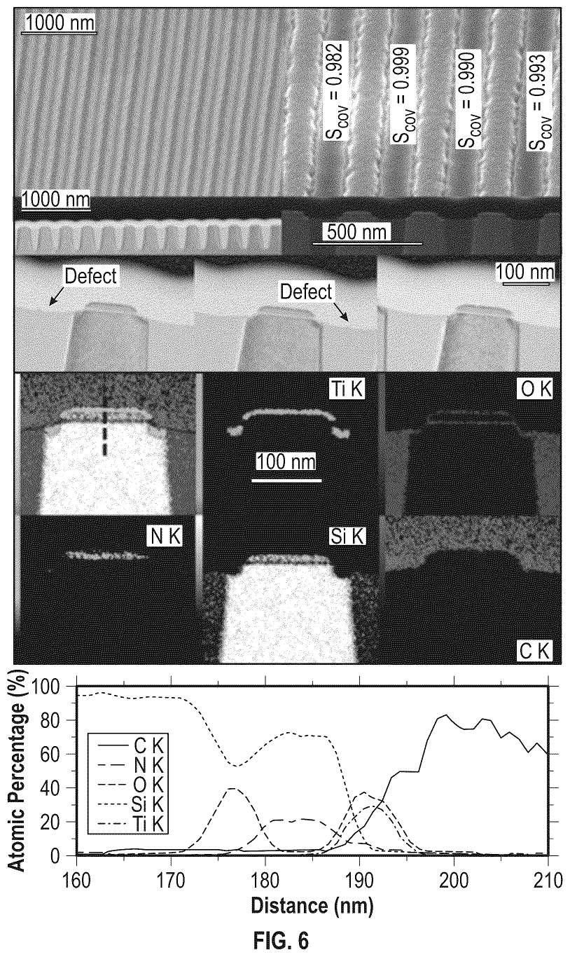

FIG. 6 presents high-resolution SEM and TEM images showcasing the selectivity and uniformity of plasma TiON deposition on patterned substrates. The images reveal TiON layers selectively deposited on SiN surfaces, with negligible material observed on SiO₂ regions. Energy-dispersive X-ray spectroscopy (EDX) analysis confirms the elemental composition of the deposited layers and demonstrates minimal contamination on nongrowth surfaces. The images also identify the absence of spurious particles on SiO₂, indicating the effectiveness of the selective deposition process. This level of precision and selectivity can enable reliable integration into high-density semiconductor patterning workflows, supporting critical scaling requirements.

### Mitigating Corner Loss

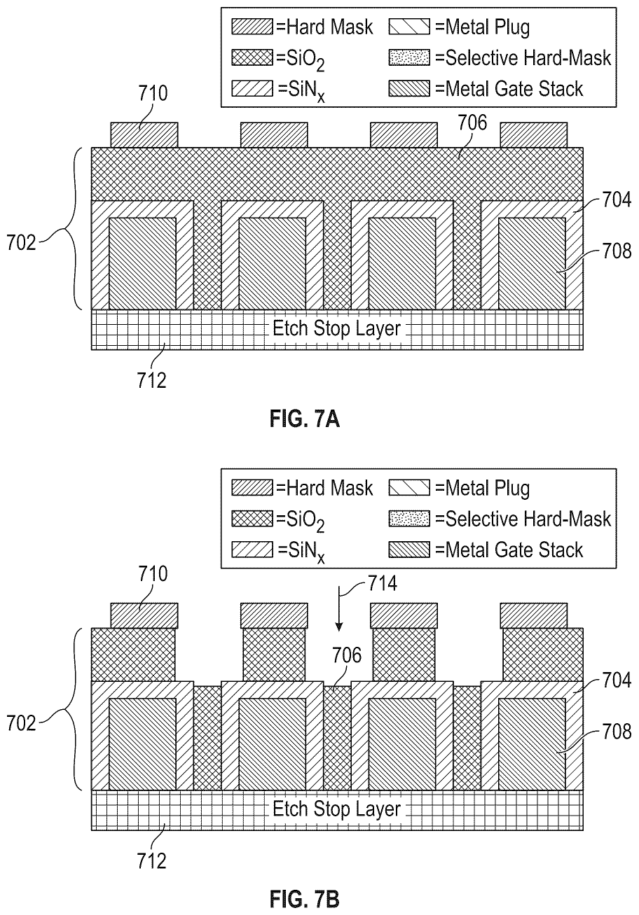

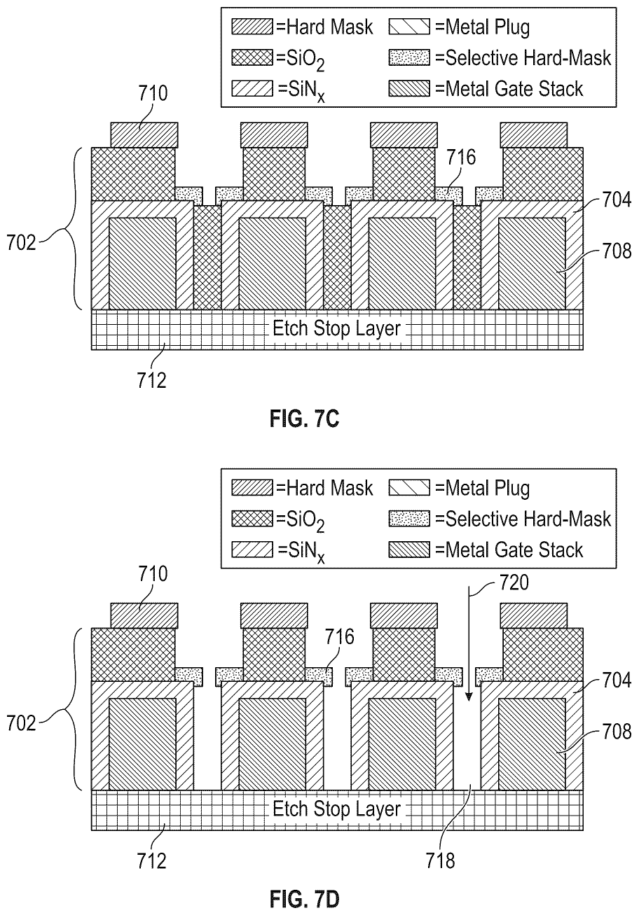

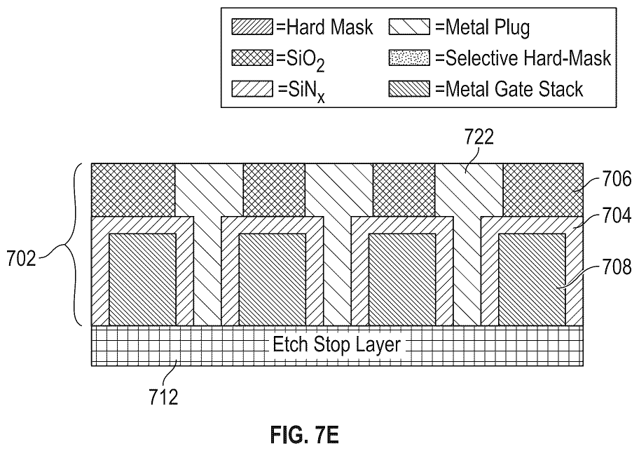

FIGS. 7A-7E describe a process sequence for improving self-aligned contact (SAC) etch techniques in semiconductor device fabrication. This process involves the selective deposition of sacrificial hard-mask materials to address challenges such as corner loss of silicon nitride (SiNₓ) spacers, pinch-off, and tapering, which can arise during SAC etching. By using the disclosed timed etching steps, selective material deposition, and/or tailored etch chemistries, the disclosed techniques support scalable and high-throughput manufacturing for semiconductor devices.

FIG. 7A depicts an example structure that can be utilized in semiconductor device fabrication. The structure includes an etch stop layer 712 at its base, with a vertically layered gate stack 702 positioned above it. The gate stack 702 can be capped by a hard mask layer 710 at its uppermost surface. Each component is arranged to provide structural, functional, and protective roles within the semiconductor fabrication process.

The etch stop layer 712 can be positioned at the bottom of the structure and can serve as a barrier to control the depth and precision of etching processes performed during device fabrication. The etch stop layer 712 can include materials such as, but not limited to, silicon carbide (SiC), carbon-doped silicon oxide (SiCOH), or other materials with sufficient etch selectivity and mechanical stability. The etch stop layer 712 can contribute to maintaining the integrity of underlying layers or substrates during fabrication.

The gate stack 702 can be located above the etch stop layer 712 and can include multiple sub-layers arranged in a vertical stack. Each layer within the gate stack 702 can serve distinct roles in electrical insulation, conduction, or structural support for the semiconductor device.

The conductive layer 708 can facilitate the conduction and regulation of electrical signals. The conductive layer 708 can include materials such as, but not limited to, tungsten (W), cobalt (Co), titanium (Ti), molybdenum (Mo), or conductive alloys. The conductive layer 708 can also support electrical connectivity within the device architecture and provide compatibility with adjacent layers for enhanced functionality. In some cases, the conductive layer 708 can form the primary metallic component of a metal gate stack.

The first layer 706 can provide structural support and protective capabilities during fabrication processes. The first layer 706 can include oxide-based compositions, including, but not limited to, silicon dioxide (SiO₂), carbon-doped silicon dioxide (c-doped SiO₂), fluorine-doped silicon dioxide (f-doped SiO₂), or porous silicon dioxide (porous SiO₂). The first layer 706 can include a low-k material and can serve as the nongrowth surface once the timed etch has been performed.

The second layer 704 can provide dielectric properties and electrical insulation. In some cases, the second layer 704 can reduce interference between the conductive layer 704 and surrounding layers. The second layer 704 can include, but is not limited to, silicon dioxide (SiO₂), hafnium oxide (HfO₂), or other high-k dielectric compositions. For example, the second layer 704 can include aluminum oxide (Al₂O₃), zirconium oxide (ZrO₂), or lanthanum oxide (La₂O₃).

A hard mask layer 710 can be positioned at an uppermost layer of the gate stack 702. The hard mask layer 710 can provide etch resistance and protect the underlying layers during subsequent processing steps. The hard mask layer 710 can include, but is not limited to, amorphous silicon, silicon nitride (SiNₓ), titanium nitride (TiN), tungsten, or other robust compositions suitable for patterning and protection. In some cases, the hard mask layer 710 cannot include silicon dioxide (SiO₂) if the fabrication process requires etching of SiO₂.

FIG. 7B depicts an etching process applied to selectively expose portions of the first layer 706, while preserving the structural and functional integrity of adjacent layers. This process can create etched gaps 714, which can facilitate subsequent processing steps, such as selective deposition or additional etching to define source/drain (S/D) contact regions.

In some cases, the selective etching process can be tailored to partially remove portions of the first layer 706, which can include SiO₂ or low-k materials, until part of the second layer 704, which can include the SiN spacer, is exposed. This process can be performed using CFₓ plasma chemistry, which can remove portions of the first layer 706 while also cleaning the exposed surface of the second layer 704 by removing native oxide and partially fluorinating the second layer 704. These effects can prepare the exposed second layer 704 for subsequent processing steps. Following this etching process, an inhibitor can be dosed to functionalize the first layer 706 (nongrowth surface) and promote selective deposition onto the second layer 704 (growth surface).

This surface treatment may involve a pretreatment process designed to alter the chemical or physical properties of the corner portions, enhancing their readiness for subsequent processing steps. Additionally, the surface treatment can include functionalizing the corner portions by introducing a surface-modifying agent. The surface-modifying agent, which can include a small molecule inhibitor, can interact with the first layer 706, which can include SiO₂ or similar materials, to prevent or limit deposition by modifying its surface properties. The small molecule inhibitor can selectively functionalize the first layer 706 to inhibit adhesion of deposited materials, while it can interact with the second layer 704, which can include SiN, to create conditions favorable for deposition. This interaction can include increasing chemical reactivity, altering surface energy, or introducing steric factors that guide deposition. By employing this selective interaction, a hardmask material, such as TiN or TiO₂, can be deposited onto the exposed corners of the second layer 704, while deposition on the surrounding first layer 706 is prevented.

Additional details regarding methods and tools related to advanced patterning and area-selective hardmask deposition that can be employed in certain embodiments of the inventive concepts described herein are disclosed in U.S. patent application Ser. No. 18/764,717, filed on Jul. 5, 2024, entitled “Area-Selective Hardmask Deposition: Methods And Tools For Advanced Patterning” (Attorney Docket No. 170964-00079), which is hereby incorporated herein by reference in its entirety.

In some cases, the etching process can be performed using fluorinated etchant chemistries to achieve selective material removal. In some cases, the fluorinated etchant chemistries can include compounds containing carbon-fluorine (CFₓ) bonds combined with co-reactants or reactive gases. For example, CF₄-based chemistries can be combined with co-reactants such as nitrogen (N₂), oxygen (O₂), or hydrogen (H₂). In some cases, hydrocarbon-fluoride-based mixtures, such as CH₂F₂ or CH₃F, can be employed with additives like argon (Ar) or helium (He) to adjust etching characteristics. In some cases, higher-order fluorinated compounds, such as octafluorocyclobutane (C₄F₈), can be used to provide enhanced selectivity at material interfaces. In some cases, chlorine-fluorine hybrid chemistries can be employed, involving fluorine-based etchants supplemented with chlorine-containing gases like Cl₂ or BCl₃. In some cases, alternative halogen-based etchants, such as sulfur hexafluoride (SF₆) or bromine trifluoride (BrF₃), can also be included for material-specific etching capabilities. In some cases, tailored co-reactants such as water vapor (H₂O), ammonia (NH₃), or hydrogen-containing gases can be used to selectively enhance reactivity with specific surface chemistries. These chemistries can be selected based on material composition, etching rate targets, or compatibility with adjacent layers. As a non-limiting example, the etching process can utilize CF₄-based chemistries combined with co-reactants such as nitrogen (N₂), oxygen (O₂), or hydrogen (H₂) to achieve selective material removal. As another non-limiting example, the etching process can include mixtures of CHₓF_{γ}-based compounds tailored with co-reactants to adjust etching rates and enhance selectivity for specific materials.

The etching process can produce a chemical contrast between the first layer 706 and the second layer 704 by utilizing etchants that preferentially react with the material of the second layer 704, such as silicon dioxide (SiO₂), while exhibiting reduced reactivity with the material of the first layer 706, such as silicon nitride (SiNₓ). This selective reactivity can facilitate the controlled removal of material from the second layer 704 without overetching or damaging the first layer 706. The selective nature of this process can enable precise patterning and preparation for subsequent fabrication steps.

FIG. 7C illustrates an example of the selective deposition of a hard-mask material 716 onto at least some of the exposed surfaces of the first layer 706. In some cases, the selective deposition of the hard-mask material 716 can address fabrication challenges, such as corner loss of silicon nitride (SiNₓ) spacers, pinch-off, and tapering, by forming a protective barrier over the first layer 706, thereby mitigating damage during etching or patterning steps.

The selective deposition can be performed using processes such as, but not limited to, chemical vapor deposition (CVD) or atomic layer deposition (ALD), which can allow for precise placement of the hard-mask material on targeted regions.

The hard-mask material 716 can provide etch resistance to support and protect the first layer 706 during subsequent fabrication steps, ensuring structural and functional reliability. The hard-mask material 716 can include, but is not limited to, titanium oxynitride (TiON), titanium nitride (TiN), or titanium dioxide (TiO₂).

In some cases, one or more inhibitors can be used to improve the selectivity of the deposition process. For example, silane-based inhibitors, such as, but not limited to, dimethylamino-trimethylsilane (DMATMS), can chemically interact with the second layer 704 to passivate its surface, reducing deposition on undesired areas. This passivation can create a surface contrast, guiding the hard-mask material 716 to adhere selectively to the first layer 706. In some cases, alternative or additional inhibitors, such as hexamethyldisilazane (HMDS) or tris(dimethylamino)silane (TDMAS), can be employed. The use of inhibitors can assist in minimizing or reducing unintentional deposition on adjacent regions and improving the accuracy of material placement for subsequent processing.

The deposition process can include reactions with precursor compounds, such as, but not limited to, titanium tetrachloride (TiCl₄), which can react with co-reactants like nitrogen (N₂), ammonia (NH₃), hydrogen (H₂), or water vapor (H₂O), to form the hard-mask material 716. In addition to TiCl₄-based reactions, other precursors, such as tetrakis(dimethylamino)titanium (TDMAT) or hafnium-based compounds, can be utilized to form alternative hard-mask materials, including, but not limited to, hafnium oxynitride (HfON) or hafnium dioxide (HfO₂).

In some cases, the selective deposition of the hard-mask material 716 can occur on both the first layer 706 and the second layer 704. However, the hard-mask material 716 may not be configured to provide protection to the second layer 704. Instead, it is primarily positioned to protect the first layer 706 during subsequent processing. In some such cases, the hard-mask material 716 deposited on the second layer 704 can be selectively removed or etched.

The described approach can provide consistent and reliable processing while maintaining compatibility with advanced device scaling and various semiconductor fabrication architectures.

FIG. 7D illustrates a subsequent etching step in the fabrication process. This step is performed to create etched gaps 720 to expose source/drain (S/D) contact regions 718 while preserving the structural integrity of the first layer 706, which is shielded by the selectively deposited hard-mask material 716. The selective deposition of the hard-mask material 716 prior to this etching step provides targeted protection for first layer 706, mitigating risks of overetching or structural degradation.

The etching process can be carried out using fluorinated etchant chemistries, similar to those employed in earlier etching step described for FIG. 7B. In some cases, adjustments in the fluorinated etchant chemistries can be tailored to target the material composition of the exposed regions.

As mentioned, the hard-mask material 716 can provide etch resistance, ensuring that the first layer 706 remains intact and that any corner loss, pinch-off, or tapering of the SiNₓ spacers is mitigated or avoided. The precise control enabled by the selective deposition and tailored etching parameters can allow for the clean and accurate exposure of the S/D contact regions 718.

FIG. 7E illustrates an example stage in the self-aligned contact (SAC) process, where the selectively deposited hard-mask material 716 and the initial hard mask layer 710 can be removed to prepare the structure for metal contact formation. Removal processes can include, but are not limited to, wet etching using hydrofluoric acid (HF) solutions or dry etching techniques employing plasma chemistries. These removal processes can be tailored to selectively eliminate the hard-mask layers while maintaining the integrity of the underlying first layer 706 and adjacent structures.

After the removal of the hard-mask material 716 and hard mask layer 710, the exposed regions, including the source/drain (S/D) contact areas 722, can be filled with metal. This metal filling process can be performed using techniques such as chemical vapor deposition (CVD), physical vapor deposition (PVD), or electroplating, depending on the specific material and process requirements.

Suitable metals for the filling process can include, but are not limited to, tungsten (W), copper (Cu), cobalt (Co), or combinations thereof. These metals can be selected based on their electrical conductivity, compatibility with surrounding materials, and structural reliability in advanced semiconductor devices. For example, tungsten (W) can provide high reliability for via fill applications, while copper (Cu) or cobalt (Co) may be employed for their superior electrical performance in interconnect structures.

The metal filling process completes the formation of the source/drain (S/D) contacts 722, which are integrated into the device architecture to facilitate efficient electrical connectivity. By employing the disclosed SAC process, material loss and process variability can be reduced, ensuring consistent and reliable device fabrication. This approach supports advanced device scaling and enables compatibility with modern semiconductor manufacturing technologies.

In some cases, the disclosed process reduces the likelihood of corner loss in SiNₓ spacers, mitigates lateral overgrowth (e.g., approximately 5-10 nm), and/or improves compatibility with existing etching and deposition equipment. By integrating selective deposition with tailored etching steps, the process offers a broader operational window and higher throughput compared to methods such as atomic layer etching (ALE). These advantages support device scaling while maintaining uniformity and consistency across complex semiconductor architectures. The method's adaptability and precision make it suitable for advanced fabrication processes in the semiconductor industry.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

The terminology used in the description of the inventive concept herein is for the purpose of describing particular embodiments only and is not intended to be limiting of the inventive concept. As used in the description of the inventive concept and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of.” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, system, etc. “consisting of,” i.e., wherein that which is claimed does not include further elements, and a composition, formulation, method, system, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

The term “substrate,” as used herein, can broadly refer to any layer and/or surface upon which processing is desired. Thus, for example, a native oxide film on the surface of a silicon or silicon nitride substrate may itself be considered a substrate for the purposes of this discussion. Likewise, layers deposited on silicon, silicon nitride, or on other base substrates may likewise be considered substrates in some embodiments. For example, in some embodiments, a multi-layer stack may be formed, and then atomic layer deposition may be performed on the top layer, or a surface of the top layer, of the stack. In such a case, the top layer may be considered the substrate. In general, the layer or layers upon which the chemical precursor is deposited and/or which reacts with the chemical precursor can be considered the substrate layer(s). The material for the substrate may be any that may be appreciated by one of skill in the art in the field of electronics and/or semiconductors.

It will be understood that when an element is referred to as being “on” another element, layer, or substrate, etc., it can be directly on the other element, layer, or substrate, etc., or intervening elements, layers, or substrates, etc. may also be present. In contrast, when an element is referred to as being “directly on” another element, layer, or substrate, etc., there are no intervening elements present.

Unless otherwise defined, all technical and scientific terms used herein have the same meaning as commonly understood by one of ordinary skill in the art to which this inventive concept belongs.

The term atomic layer deposition, or ALD, as used herein, can broadly refer to the level of layer dimensional control in a deposition process, that can be achieved at the angstrom (Å) or sub-angstrom level. Thus, deposition of or growth of a layer through atomic layer deposition, or a cycle thereof, may generally correspond to the size of atoms and/or molecules. The average added layer thickness per cycle of ALD can be less than 1 Å (0.1 nm) per deposition cycle, for example, less than about 0.1 Å, about 0.1 Å, about 0.2 Å, about 0.3 Å, about 0.4 Å, about 0.5 Å, about 0.6 Å, about 0.7 Å, about 0.8 Å, or about 0.9 Å per cycle, or more than 1 Å per cycle, for example, about 1 Å, about 1.1 Å, about 1.2 Å, about 1.3 Å, about 1.4 Å, about 1.5 Å, about 1.6 Å, about 1.7 Å, about 1.8 Å, about 2 Å, about 3 Å, about 4 Å, about 5 Å, about 6 Å, about 7 Å, about 8 Å, about 9 Å, about 10 Å (1 nm), about 11 Å, about 12 Å, about 13 Å, about 14 Å, about 15 Å, about 16 Å, about 17 Å, about 18 Å, about 19 Å, or about 20 Å (2 nm) per cycle, or any number between about 0.1-30 Å per deposition cycle. In some embodiments, the average added layer thickness per cycle is between about 0.1-2 Å, about 0.2-2 Å per deposition cycle, about 0.3-2 Å, about 0.4-2 Å per deposition cycle, about 0.5-2 Å per deposition cycle, about 0.6-4 Å per deposition cycle, or about 0.1-4 Å per deposition cycle.

The layer prepared by the methods of the inventive concept may have a thickness of greater than or equal to 1 nm, greater than or equal to 2 nm, greater than or equal to 3 nm, greater than or equal to 4 nm, greater than or equal to 5 nm, greater than or equal to 6 nm, greater than or equal to 7 nm, greater than or equal to 8 nm, greater than or equal to 9 nm, greater than or equal to 10 nm, greater than or equal to 11 nm, greater than or equal to 13 nm, greater than or equal to 14 nm, greater than or equal to 15 nm, greater than or equal to 16 nm, greater than or equal to 18 nm, greater than or equal to 20 nm, in a range of greater than or equal to about 3 nm to about 20 nm, in a range of greater than or equal to about 5 nm to about 20 nm, or in a range of greater than or equal to about 5 nm to about 15 nm.

The choice of chemical precursor or precursors to deposit the metal, metal oxide, metal nitride, or metal oxynitride films according to methods of the inventive concept are not particularly limited, and may be any that may be appreciated by one of skill in the art. In some embodiments, the chemical precursor may include, for example, silicon (Si), titanium (Ti), hafnium (Hf), tantalum (Ta), tin (Sn), molybdenum (Mo), or aluminum (Al). In some embodiments, the chemical precursor includes titanium (Ti), for example, TiCl₄, titanium tetraisopropoxide (TTIP), or tetrakis(dimethylamino)titanium (TDMAT). In some embodiments, the chemical precursor may be a metal halide, for example, SiCl₄, Si₂Cl₆, SiH₂Cl₂, AlCl₃, Al₂Cl₆, FeCl₃, HfCl₄, MoO₂Cl₂, MoF₆, MoCl₅, TaF₅, TaCl₅, TaI₅, WF₆, WCl₆, or ZrCl₄. In some embodiments, the chemical precursor may be TiCl₄. In some embodiments, the chemical precursor may be a silane, e.g., a trihalo-alkysilane, such as but not limited to trichloro(octadecyl)silane, a trimethoxy-alkylsilane or a trimethoxy-aminosilane, such as 3-aminopropyltrimethoxysilane. Similarly, the deposition process is not particularly limited. In some embodiments, the deposition may be a thermal deposition process. In some embodiments, the deposition may be or include a plasma deposition process.

In addition, the co-reactant, or co-reactants, to deposit the metal, metal oxide, metal nitride, metal oxynitride, metal oxycarbide, metal carbonitride, metal carbide, metal sulfide, or metal oxysulfide, or metal (oxy)selenide films according to methods of the inventive concept are not particularly limited, and may be any that may be appreciated by one of skill in the art, for example, H₂O, H₂O₂/H₂O mixtures, O₂, O₃, NH₃, or N₂H₄, or H₂S, or H₂Se, or a hydrocarbon, e.g., CH₄, or a halogenated hydrocarbon, e.g., CHX₃, CH₂X₂, etc. In some embodiments, wherein the deposition is a thermal deposition process, the co-reactant may be H₂O, such as in thermal titanium oxide (t-TiO₂) deposition. In some embodiments, wherein the deposition is a plasma deposition process, the co-reactant may include a gas, for example, N₂, H₂, Ar, O₂, or H₂S, or H₂Se or a mixture of gases, for example, N₂/H₂, H₂/Ar, or N₂/Ar. In some embodiments, the co-reactant may be a N₂/H₂ plasma, such as in plasma titanium oxynitride (p-TiON) deposition. In some embodiments, the plasma deposition may include an NH₃ plasma.

The number of ALD or deposition cycles performed in the methods of the present inventive concept is not particularly limited, and may be any number of cycles that would be appreciated by one of skill in the art. For example, the number of deposition cycles in the process may be between 1 and about 1,000 cycles. In some embodiments, the number of deposition cycles may be between about 1-600 cycles, for example, 1 cycle, about 5 cycles, about 10 cycles, about 20 cycles, about 30 cycles, about 40 cycles, about 50 cycles, about 60 cycles, about 70 cycles, about 80 cycles about 100 cycles, about 150 cycles, about 200 cycles, about 250 cycles, about 300 cycles, about 350 cycles, about 400 cycles, about 450 cycles, about 500 cycles, about 550 cycles, or about 600 cycles, or any number of deposition cycles between and including 1 deposition cycle and about 1,000 deposition cycles. Each deposition cycle may include exposing the substrate to alternating pulses/doses of a chemical precursor and a co-reactant. In some embodiments, the deposition cycle may include exposing the substrate to a pulse/dose, or more than one pulse/dose, for example, 2, 3, 4, 5, 6 pulses/doses, etc. of a chemical precursor, and a pulse/dose, or more than one pulse/dose, for example, 2, 3, 4, 5, 6 pulses/doses, etc. of a co-reactant. Prior to the deposition cycle(s), the surface on which deposition is to take place may be: precleaned, for example, with a plasma/plasma etching step, such as exposure to, or multiple exposures/“cycles” to a CF₄/N₂ plasma, to remove, for example, a native oxide film that may be present on the surface; and/or functionalized, for example, through exposure to, or multiple exposures/“cycles” to a small molecule inhibitor (SMI), for example, an aminosilane, such as bis(N,N-dimethylamino)dimethylsilane (BDMADMS) or (N,N-dimethylamino)trimethysilane (DMATMS). In some embodiments, the aminosilane/SMI may be hexamethyldisilazane (HMDS) or a silatrane, e.g., methylsilatrane, or related compounds. In some embodiments, the SMI may be DMATMS. In some embodiments, functionalization of the surface may selectively passivate remaining exposed hydroxyl groups on the nongrowth surface of the substrate, for example, an oxide layer, such as an SiO₂ layer or portion of a substrate, thus forming an effective inhibition layer for subsequent ALD. Accordingly, any compound/SMI capable of selectively passivating remaining exposed hydroxyl groups on the nongrowth surface of the substrate may be used/envisioned without departing from the scope of the inventive concept.

Accordingly, in some embodiments, a substrate, on which deposition is to take place, may be: precleaned, for example, with a plasma etching step; functionalized, for example, by exposure to an SMI; and followed by at least one deposition cycle including exposure to a precursor and a co-reactant, to provide a layer selectively deposited on a GS vs. an NGS.

In other embodiments, the deposition cycle may include exposure of a surface on which deposition of a film/layer is to take place, for example a surface of a substrate, to an SMI, followed by exposure of the surface to a precursor, and exposure of the surface to a co-reactant. Accordingly, the substrate, on which deposition is to take place, may be precleaned, followed by at least one deposition cycle including: functionalizing the surface, for example, by exposure to an SMI; exposing the surface to a precursor; and exposing the surface to a co-reactant, to provide a layer selectively deposited on a GS vs. an NGS.

In some embodiments, the methods of the inventive concept may include a back-etching step with, for example, exposure to a plasma after the at least one deposition cycle(s). In some embodiments, the chemistry of the back-etching plasma is the same plasma employed for pre-deposition etching/cleaning to limit cross-contamination issues. For example, the precleaning/pre-deposition plasma and the back-etching plasma may both be a mixture, for example, a CF₄/N₂ plasma, but is not limited thereto. In some embodiments, the mixture may include, CF₄, CHF₃, and/or CₓH_{y}F_{z} with H₂, O₂, N₂, and/or Ar. In some embodiments, the back-etching plasma may include Cl₂, and/or mixtures thereof with H₂, N₂, O₂, and/or Ar. In some embodiments, the back-etching plasma may include NH₃, and/or mixtures thereof with N₂ and/or H₂. The exposure of the layer or layers deposited on a substrate to the back-etching plasma may include, for example, a single exposure, or may include multiple exposures/“cycles” to the back-etching plasma.

The exposure of the substrate to a plasma to preclean the substrate prior to deposition, and the exposure of the substrate to a plasma to back-etch following deposition, may include a single plasma exposure or “cycle” on a rotating workpiece/rotary spatial ALD reactor, as opposed to an ALD deposition cycle, or may include multiple plasma exposures/“cycles” on the ALD reactor. The number of plasma exposures/“cycles” prior to deposition and/or postdeposition back-etching is not particularly limited. This number may be anywhere from 1 to about 100 exposures/“cycles.” In some embodiments, the number of pre-deposition plasma exposures/“cycles” may be between about and including 50 to about 100 exposures/“cycles of precleaning plasma prior to ALD. In some embodiments, the number of post-deposition back-etching plasma exposures/“cycles” may be about and including 20 to about 80 exposures/“cycles” of back-etching plasma following ALD.

In some embodiments, when functionalizing the substrate on which deposition is to take place by exposure to an aminosilane SMI prior to ALD, the exposure of the substrate to the functionalizing SMI may include a single exposure or “cycle” on a rotating workpiece/rotary spatial ALD reactor, or exposure of the substrate to the functionalizing SMI may include multiple plasma exposures/“cycles” on the ALD reactor. For example, the number may be anywhere from 1 to about 10 exposures/“cycles,” for example, the number of exposures/“cycles” may be about 5 exposures/“cycles” when functionalizing the substrate prior to ALD.

The temperature and/or pressure at which the methods of the present inventive concept are performed are not particularly limited. Nevertheless, in some embodiments, the temperature at which the ALD methods are performed between and including about 100° C. and about 300° C. In some embodiments, the temperature is between and including about 100° C. and about 250° C. In some embodiments, the temperature is between and including about 100° C. and about 200° C. In some embodiments, the pressure at which the ALD methods are performed at atmospheric or ambient pressures.

The present inventive concept overcomes the limitations and disadvantages of prior techniques. The inventive concept provides ALD techniques, which enable the selective deposition of metals, metal oxides and metal oxynitrides on a surface or substrate. According to embodiments of the present inventive concept, selective deposition may refer to deposition of, for example, a material, such as a metal or a material including a metal, on a first portion of a surface or substrate, such as a GS, with no detectable deposition, with minimal deposition, or with significantly less or reduced deposition, of the material on a second portion of the substrate or surface, such as an NGS. The first and second portions of the surface or substrate may be of differing materials or composition. For example, in some embodiments, the first portion of the surface may be a nitride layer, for example, a silicon nitride (SiN) layer, a carbon-doped silicon nitride (silicon carbon nitride, SiCN) layer, or a metal nitride layer such as HfN, TiN, and/or ZrN, i.e., exemplary nitrides of group-IV metals/elements, or SnN, or nitride layers that may include germanium (Ge) or lead (Pb), and the second portion of the surface may be an oxide layer including hydroxyl groups from SiO₂, such as a silicon oxide (SiO₂) layer, a carbon-doped silicon oxide (C:SiO₂) layer, or a silicon carbide (SiC) layer. In some embodiments, the first portion of the surface may be crystalline silicon (c-Si).

“Selective deposition,” “area selective deposition” (ASD), and “area selective atomic layer deposition” (AS-ALD) refer to processes that lead to deposition of materials on only desired area of, for example, a patterned substrate. The patterned substrate may include areas or portions, and deposition is desired on one area or portion but not the other. Accordingly, selective deposition may include deposition of, for example, a material, such as a metal or a material including a metal, on a first portion (GS) of a surface or substrate, with no deposition, with minimal deposition, or with significantly less or reduced deposition, of the material on a second portion (NGS) of the substrate or surface. The first and second portions/areas of the surface or substrate may be of differing materials or composition.

In some embodiments, the selectivity of deposition may be defined, for example, as discussed in Gladfelter (1993) Chem. Mater. 5(10), 1372-1388, and as set forth by Equation (1):

$$S = \frac{{X}_{G S} - {X}_{N G S}}{{X}_{G S} + {X}_{N G S}} \qquad ( 1 )$$

wherein X_{GS} and X_{NGS} are measurements of the amount of material deposited (thickness or area coverage) on the growth surface (GS) and on the nongrowth surface (NGS). S may have a value between 0 and 1, wherein S=0 is indicative of no selectivity of deposition on the GS and the NGS, and wherein S=1 is indicative of complete (100%) selectivity of deposition on the GS and the NGS. In some embodiments, the methods of the inventive concept may have a selectivity of deposition S of ≥0.80, ≥0.85, ≥0.88, ≥0.90, ≥0.91, ≥0.92, ≥0.93, ≥0.94, ≥0.95, ≥0.96, ≥0.97, ≥0.98, or ≥0.99, or even S=1.00, wherein no detectible deposition takes place/is observed on the NGS.

What is claimed is:

1. A method for mitigating corner loss in semiconductor fabrication, the method comprising:
performing a first timed etching process to selectively remove portions of a first material layer (SiO₂) of a substrate having a multi-layered semiconductor structure, wherein the first etching process exposes corner portions of a second material layer (SiN) adjacent to the first material layer;
applying a surface treatment to the substrate, wherein the surface treatment inhibits deposition of a hardmask material on the first material layer and facilitates deposition of the hardmask material on the second material layer;
depositing the hardmask material onto the corner portions of the second material layer, wherein deposition of the hardmask material is selective due to at least one of chemical selectivity, surface reactivity, or steric hindrance provided by the surface treatment;
performing a second etching process to selectively remove additional portions of the substrate, wherein the hardmask material mitigates etch-induced degradation of the corner portions during the second etching process.

2. The method of claim 1, wherein the pretreatment process comprises a plasma process to remove native oxide layers from the corner portions of the first material layer, and wherein the surface-modifying agent comprises an aminosilane small molecule inhibitor.

3. The method of claim 2, wherein the aminosilane small molecule inhibitor comprises silane-based inhibitors, including dimethylamino-trimethylsilane (DMATMS), hexamethyldisilazane (HMDS), or tris(dimethylamino)silane (TDMAS).

4. The method of claim 1, wherein the first etching process employs a fluorinated etchant to selectively remove the portions of the second material layer.

5. The method of claim 4, wherein the fluorinated etchant comprises a CHₓF_{y}-type fluorinated etchant, wherein x and y are integers representing a number of hydrogen and fluorine atoms, respectively.

6. The method of claim 1, wherein depositing the hardmask material comprises utilizing a first precursor of titanium tetrachloride (TiCl₄) with ammonia (NH₃) or a second precursor of a mixture of nitrogen (N₂) and hydrogen (H₂), and water vapor (H₂O).

7. The method of claim 1, wherein depositing the hardmask material comprises utilizing a precursor of tetrakis(dimethylamino)titanium (TDMAT) or bis(ethylmethylamino)titanium (BEMAT).

8. The method of claim 1, wherein the hardmask material comprises titanium oxynitride (TiON), titanium nitride (TiN), titanium dioxide (TiO₂), hafnium oxynitride (HfON), or hafnium dioxide (HfO₂).

9. The method of claim 1, wherein depositing the hardmask material comprises utilizing an atomic layer deposition (ALD) process, wherein the ALD process includes alternating exposures of titanium tetrachloride (TiCl₄) and water vapor (H₂O) to form the hardmask material.

10. The method of claim 1, wherein the second etching process utilizes a chlorine-based etchant comprising chlorine (Cl₂), boron trichloride (BCl₃), or a mixture thereof, or a fluorine-based etchant comprising compounds with the formula CₓH_{γ}F_{z}, including CF₄ or CHF₃.

11. The method of claim 1, further comprising depositing a conductive material into regions exposed by the second etching process to form electrical interconnects, wherein the conductive material comprises tungsten, copper, cobalt, or alloys thereof.

12. The method of claim 11, further comprising removing the hardmask material prior to depositing the conductive material.

13. The method of claim 1, wherein the surface treatment comprises applying a small molecule inhibitor to selectively functionalize the first material layer, wherein the small molecule inhibitor inhibits deposition of the hardmask material on the first material layer and allows selective deposition onto the exposed corner portions of the second material layer after the first timed etching process has partially removed the first material layer to expose the second material layer.

14. The method of claim 1, wherein the second material layer comprises silicon nitride (SiNₓ), amorphous silicon, doped polysilicon, silicon carbide (SiC), or silicon oxynitride (SiON).

15. The method of claim 1, wherein the surface treatment and hardmask material deposition are performed in a continuous processing chamber to limit reoxidation of the corner portions of the first material layer.

16. The method of claim 1, wherein the hardmask material enhances etch selectivity between the first material layer and the second material layer during the second etching process.

17. The method of claim 1, wherein the hardmask material is conformally deposited onto the corner portions of the first material layer, achieving a step coverage of at least 90%.

18. A system for semiconductor fabrication, the system comprising:
a processing chamber configured to perform a first etching process to selectively remove portions of a first material layer of a substrate having a multi-layered semiconductor structure, wherein the first etching process exposes corner portions of a second material layer adjacent to the first material layer;
a plasma treatment unit within the chamber, configured to pretreat the substrate with a surface treatment, wherein the surface treatment inhibits deposition of a hardmask material on the first material layer and facilitates deposition of the hardmask material on the second material layer;
a deposition system configured to deposit the hardmask material onto the corner portions of the second material layer, wherein deposition of the hardmask material is selective due to at least one of chemical selectivity, surface reactivity, or steric hindrance provided by the surface treatment; and
an etching module configured to perform a second etching process to selectively remove additional portions of the substrate, wherein the hardmask material mitigates etch-induced degradation of the corner portions during the second etching process.

19. A semiconductor structure fabricated by a method comprising:
performing a first timed etching process to selectively remove portions of a first material layer of a substrate having a multi-layered semiconductor structure, wherein the first etching process exposes corner portions of a second material layer adjacent to the first material layer;
applying a surface treatment to the substrate, wherein the surface treatment inhibits deposition of a hardmask material on the first material layer and facilitates deposition of the hardmask material on the second material layer;
depositing the hardmask material onto the corner portions of the second material layer, wherein deposition of the hardmask material is selective due to at least one of chemical selectivity, surface reactivity, or steric hindrance provided by the surface treatment;
performing a second etching process to selectively remove additional portions of the substrate, wherein the hardmask material mitigates etch-induced degradation of the corner portions during the second etching process.
